(19) United States
(12) Patent Application Publication
(10) Pub. No.: US 2011/0117376 A1
(43) Pub. Date: May 19, 2011

(54) Method of Gallium Nitride growth over metallic substrate using Vapor Phase Epitaxy

(76) Inventors: Mingwei Zhu, Sunnyvale, CA (US); Theeradetch Detchprohm, Niskayuna, NY (US); Christian Wetzel, Troy, NY (US)

(21) Appl. No.: 12/947,409

(22) Filed: Nov. 16, 2010

Related U.S. Application Data
(60) Provisional application No. 61/261,901, filed on Nov. 17, 2009.

(51) Int. Cl. C30B 25/18; B32B 15/04

(52) U.S. Cl. 428/457; 117/88

(57) ABSTRACT

The current invention introduces a method of crystal film's growth of Gallium Nitride and related alloys over a novel class of the substrates using Vapor Phase Epitaxy technique. This said novel class of the substrates comprises single crystal lattice matched, partially matched or mismatched metallic substrates. The use of such substrates provides exceptional thermal conductivity and application flexibility, since they can be easily removed or patterned by chemical etching for the purposes of additional contact formation, electromagnetic radiation extraction, packaging or other purposes suggested or discovered by the skilled artisan. In particular, if patterned, the remaining portions of the said substrates can be utilized as contacts to the semiconductor layers grown on them. In addition, the said metallic substrates are significantly more cost effective than most of the conventional substrates. The use of Vapor Phase Epitaxy allows growing the epitaxial layers with different and/or variable alloy composition, as well as heterostructures and superlattices.

### FIELD OF THE DISCLOSURE

Aspects of the invention relate to the compound semiconductor material growth technique over the crystalline metallic substrate, and in particular, to the Vapor Phase Epitaxy (VPE) of Gallium Nitride, Indium Nitride, Aluminum Nitride and their combinative compounds over the crystalline Tungsten substrate.

### BACKGROUND OF THE DISCLOSURE

Gallium Nitride and related alloys (Indium Nitride, Aluminum Nitride and their ternary and quaternary alloys) are known for their potential applications in semiconductor industry, in particular in electronics and optoelectronics. Yet the most limiting factor for these materials' practical usage is the absence of the native substrate. Instead, the single crystal Sapphire, Silicon Carbide or Silicon substrates are commonly used to grow epitaxial films of Gallium Nitride and related alloys.

The use of other materials as a substrate results in high defect densities in the obtained epitaxial films due to crystalline lattice mismatch, differences in thermal expansion coefficients and nucleation imperfectness. In addition, Sapphire substrate has much lower thermal conductivity than Gallium Nitride itself and therefore limits the power dissipation of the devices and structures formed on it; Silicon Carbide remains extremely expensive and therefore not suitable for consumer applications; and Silicon has the largest lattice mismatch and therefore highest arising defect density among these popular substrates.

The search for the affordable substrate alternatives is, therefore, open. Recently, several groups reported successful growth of Gallium Nitride epitaxial films over metal substrates, such as Fe, W, Au, Cu, Mo, etc. The details of these studies are given in the following references: K. Okamoto, S. Inoue et al, “Epitaxial growth of GaN films grown on single crystal Fe substrates”, Applied Physics Letters 93, 251906, 2008; Guoqiang Li, Tae-Won Kim et al, “Epitaxial growth of single-crystalline AIN films on tungsten substrates”, Applied Physics Letters 89, 241905, 2006; K. W. Tay, C. L. Huang, and L. Wu, “Highly c-axis oriented thin AIN films deposited on gold seed layer for FBAR devices”, Journal of Vacuum Science and Technology, B 23, p. 1474, 2005; S. Inoue, K. Okamoto et al, “Epitaxial growth of GaN on copper substrates”, Applied Physics Letters, V. 88, 261910, 2006; S. Hirata, K. Okamoto et al, “Epitaxial growth of AIN on single crystal Mo substrates”, Journal of Solid State Chemistry, V. 180, p. 2335, 2007. The technique used in these experiments was Pulsed Laser Deposition that allows for relatively low substrate temperature during the epitaxy and therefore prevents the substrate from reacting with other materials present in the reactor, in particular with the process chemicals during a deposition.

At the same time, the Pulsed Laser Deposition technique has several important limitations, such as the necessity of switching the process chemicals' sources while fabricating the structure that consists of several layers of different Al, Ga and In composition; the inability of gradual change in composition, etc.

In contrast to the Pulsed Laser Deposition, the conventional method most frequently used for GaN and related alloys' epitaxy, namely Vapor Phase Epitaxy (VPE) produces the semiconductor epitaxial films of comparable or better crystalline quality, offering at the same time much greater flexibility in the use of the process chemicals' sources. As a result, it allows obtaining the layers with varied composition, both graded and abruptly changed, depending on the application needs, during one deposition cycle. Such layers are the base for many types of advanced devices' designs, such as heterostructure-based Light Emitting Diodes (LEDs), Laser Diodes (LDs), High Electron Mobility Transistors (HEMTs), Heterostructure Bipolar Transistors (HBTs), varactors, Surface Acoustic Wave (SAW) resonators, etc.

Combining the benefits of the Vapor Phase Epitaxy and of the usage of metallic substrates, which have usually much better thermal conductance than Sapphire, for GaN and related materials growth is, therefore, an important new development for the semiconductor industry, electronics and optoelectronics.

### SUMMARY OF THE INVENTION

Aspects of the invention are directed to the Gallium Nitride (GaN) semiconductor and related alloys' crystal growth over a single crystal or polycrystalline metallic substrate using Vapor Phase Epitaxy (VPE), including but not limited to, Metal Organic Vapor Phase Epitaxy (MOVPE), also known as Metal Organic Chemical Vapor Deposition (MOCVD), and Hydride Vapor Phase Epitaxy (HVPE).

An objective of present invention is to provide a method for compound semiconductor, in particular AIN, GaN, InN and their compounds, crystal growth that makes use of the new class of substrates to improve the current technology in aspects of—including, but not limited to—cost reduction, thermal management, substrate removal and/or patterning, and crystal quality.

According to the present invention this can be achieved by applying the VPE technique of Nitride semiconductor's growth to the lattice-matched or one-axis lattice-matched single crystal and/or polycrystalline metallic substrate. More specifically, the said single crystal or polycrystalline metallic substrate, having the surface(s) of the crystallographic orientation lattice-matched or one-axis lattice-matched to the said Nitride semiconductor or compound, is placed into the VPE reactor in Hydrogen ambient, where it is heated up uniformly to the deposition temperature in the range 500-1500 degrees Celsius, or limited by the melting point of the said substrate. For the exemplary comparison, the melting point of Tungsten exceeds 3400 degrees Celsius. After the desired temperature is reached uniformly over the said substrate, the sources of chemical components of the deposition reaction are activated and deactivated at specific pre-selected moments of time. By doing so, the high quality epitaxial layers of Nitrides are obtained by preventing the reaction of the chemical components of the deposition reaction with the substrate material.

It is understood that the choice of the specific moments for the activation of the sources of chemical components of the deposition reaction, as well as the time durations during which the said sources remain active, is critical for the grown crystal quality and depend on the desired composition of the material to be grown. In the practical example described below, the said sources were activated simultaneously. The simultaneous source activation means here that the time interval between the activation of the said sources is less than the estimated time for the said components to reach from the said sources to the substrate surface. However, for some practical reasons a skilled artisan may prefer different time pattern for the said sources' usage. To mention some, in the U.S. Patent Application 2007/0141258 by Qhalid Fareed, Remigijus Gaska and Michael Shur, the pulsed sequences of the precursor gases delivery to the reaction chamber is discussed as applied to the growth of Gallium Nitride and Aluminum Gallium Nitride layers over traditional substrates. Similar technique could be discovered by a skilled artisan as applied to the present invention.

In another embodiment of the invention, no lattice match between the substrate and the deposited materials is used. Instead, the surface of the metallic substrate is prepared in such a way that it is nearly ideal crystalline surface, with low surface roughness, absence of scratches or steps, and with minimal contamination of absorbed impurities. By the use of the same technique as described above for the prevention of the substrate's reaction with the chemical components of the deposition, the high quality epitaxial layers of Nitrides are also obtained due to the absence of the defects in the substrate's morphology that would translate into the epitaxial layer's defects.

In yet another embodiment of the present invention, the growth is performed on the polycrystalline metal substrate of arbitrary shape, for example metal wire, while the high crystalline quality of the grown semiconductor is achieved due to the regrowth effect.

The wording “chemical components of the MOVPE deposition reaction”, for the purpose of present invention, means Trimethyl Gallium, Trimethyl Aluminum, Trimethyl Indium, and Ammonia. The wording “chemical components of the HVPE deposition reaction”, for the purpose of present invention, means Gallium Chloride, Aluminum Chloride, Indium Chloride, and Ammonia.

In a first aspect of the present invention, the single crystal metallic substrate is used for the Nitride semiconductor's growth using VPE technique.

In a second aspect of the present invention, the substrate's surface with the crystallographic orientation lattice-matched, one-axis lattice-matched or not matched to the said Nitride semiconductor or compound is selected, cleaned and prepared for the deposition.

In a third aspect of the present invention, the free-shaped polycrystalline metallic substrate is used for the Nitride semiconductor's growth using VPE technique

In a fourth aspect of the present invention, the sources of chemical components of the VPE reaction are activated simultaneously to ensure high quality crystal growth.

### BRIEF DESCRIPTION OF THE DRAWINGS

These and other features of the present invention will be more readily understood from the following brief description of the various aspects of the invention taken in conjunction with the accompanying drawings, which relate, for illustrative purpose only, to the MOVPE growth technique, but can be reformulated to be applied to other VPE techniques, such as HVPE, by any artisan skilled in the art.

FIG. 1 depicts an example of one-axis lattice-matching of GaN Wurtzite to the metallic substrate.

FIG. 2 presents the microphotograph of the single crystal metallic substrate's surface prior to MOVPE deposition.

FIG. 3 gives a high-resolution Scanning Electron Microscopy image of the surface of GaN deposited using MOVPE over the substrate of FIG. 2.

FIG. 4 depicts a lower-resolution Scanning Electron Microscopy view of the surface of GaN deposited using MOVPE over the substrate of FIG. 2.

FIG. 5 shows the X-ray diffraction data confirming high crystalline quality of GaN deposited using MOVPE over the substrate of FIG. 2.

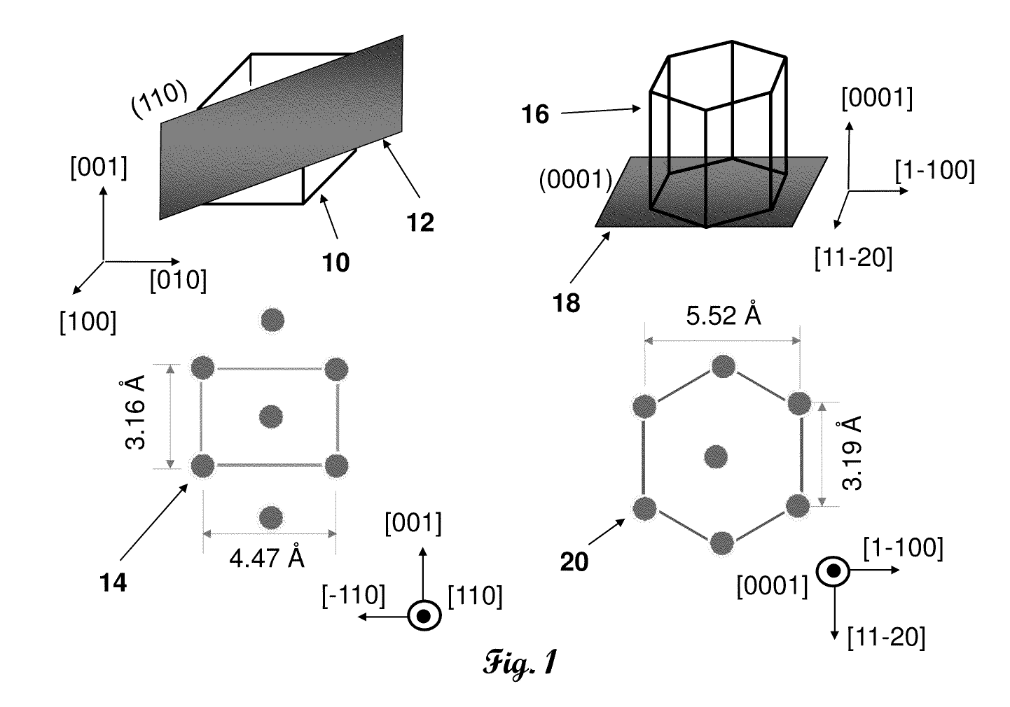

It is noted that FIG. 1 of the drawings accompanying the invention description is not to scale. The drawings are intended to depict only typical aspects of the invention, and therefore should not be considered as limiting the scope of the invention.

### DETAILED DESCRIPTION

FIG. 1 depicts schematically the two-dimensional projection 10 of the three-dimensional elementary atomic cell of crystalline tungsten in alpha-phase and position of the (110) crystalline plane 12 crossing the said elementary cell. The atoms' arrangement 14 within the said (110) plane is provided, with the linear dimensions given in Angstroms. For comparison, the c-plane of wurtzite GaN (002) with atoms' arrangement 16 with the linear dimensions given in Angstroms is also presented. Along one of the axes, the atoms arrangement within the said planes represents nearly perfect lattice matching, with the mismatch value as low as 1%.

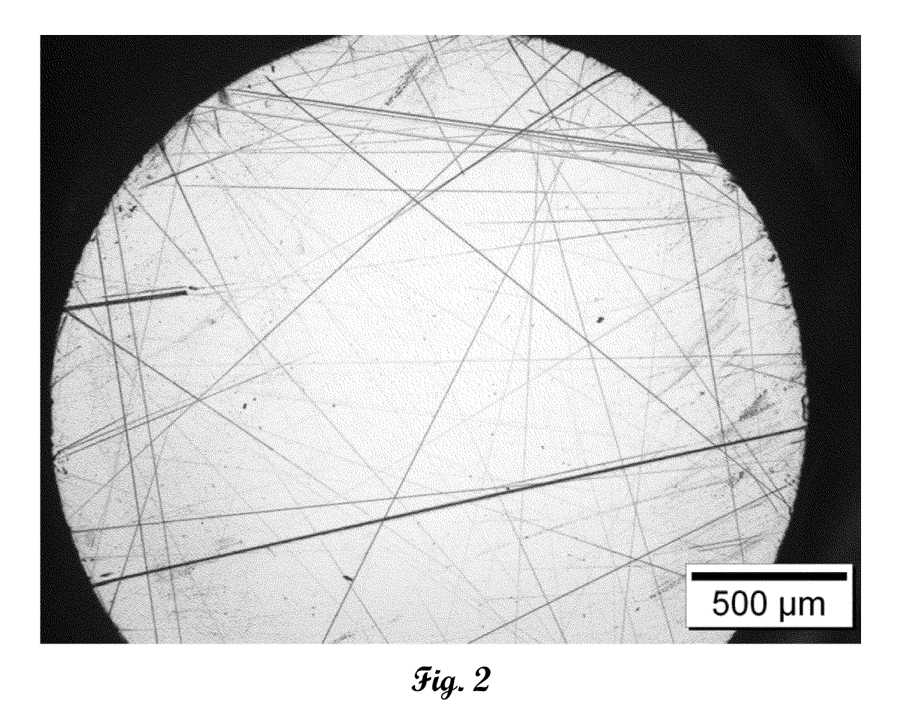

The example substrates for the present invention were prepared using the slicing of a single crystal tungsten rod. The diameter of the said rod was 3 mm. FIG. 2 presents the microphotograph of the surface of single crystal tungsten substrate prepared for MOVPE deposition. The scratches seen in the FIG. 2 resulted from mechanical polishing. It is understood that other existing or later discovered polishing methods available to a skilled artisan may result in less to no scratches and a higher quality, more uniform substrate preparation.

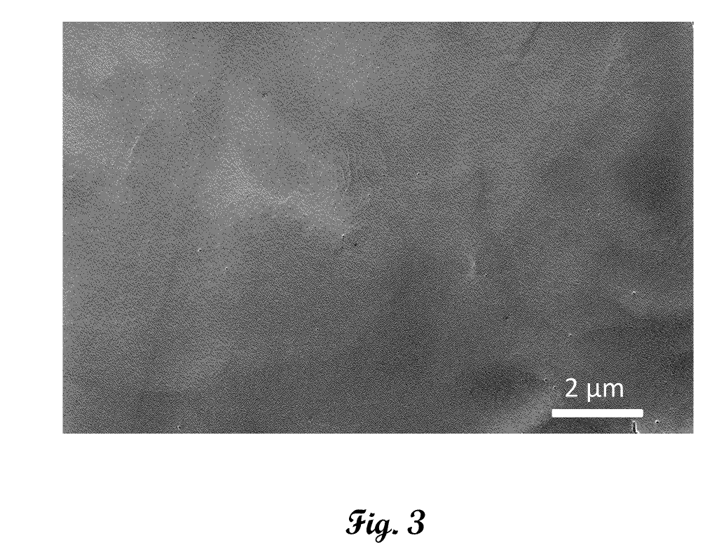

FIG. 3 shows an image of the surface of GaN deposited by MOVPE over the substrate of FIG. 2 taken by high-resolution Scanning Electron Microscopy. The surface shown corresponds to the scratch-free window in the substrate. Good and smooth GaN surface can be achieved, with only a few surface steps and pinholes presented over the area of about a hundred square microns.

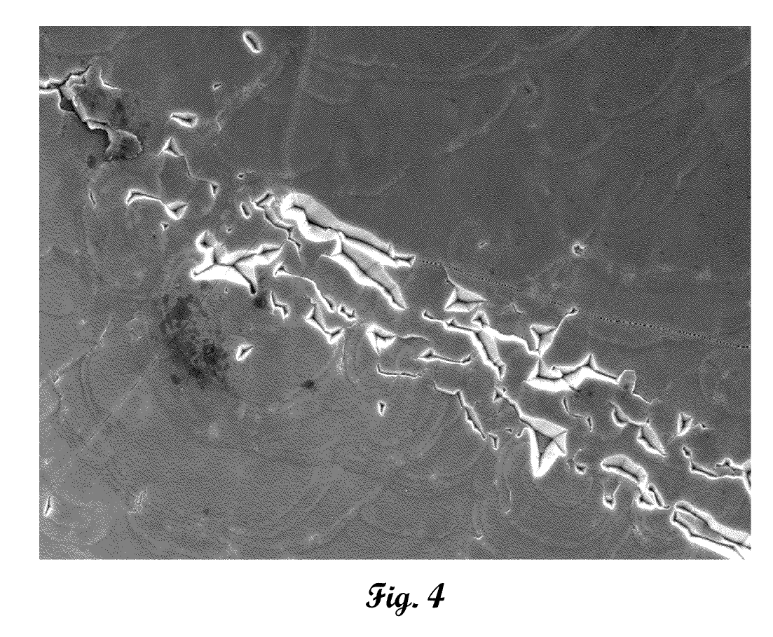

FIG. 4 shows an image of the surface of GaN deposited by MOVPE over the substrate of FIG. 2 taken by high-resolution Scanning Electron Microscopy. The surface shown corresponds to the scratch area in the substrate. A large number of surface steps, cracks and large hexagonal pinholes can be seen. This result demonstrates that the grown GaN layer repeats the morphology of the metallic substrate. This in turn shows that the presented invention is further extendable to larger diameters of the substrates, upon availability of the said substrates.

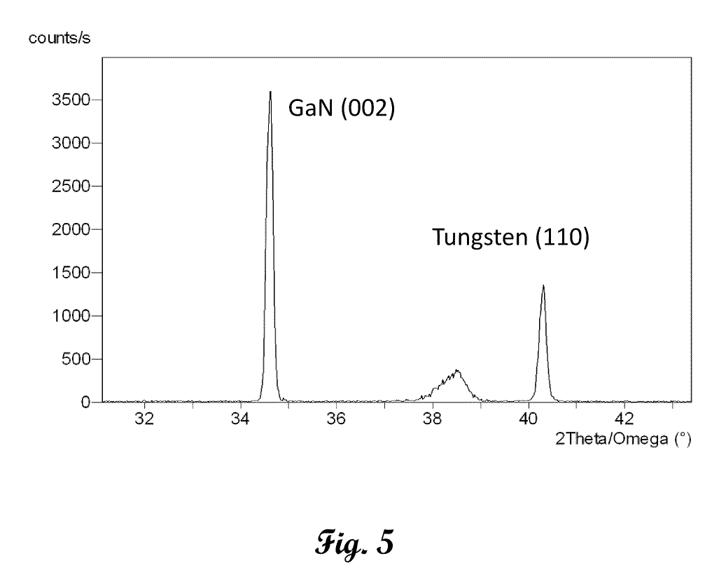

The X-ray diffraction data measured from the GaN sample grown by MOVPE on the tungsten substrate, as discussed above, is shown in FIG. 5. The data shows the peaks corresponding to GaN (002) and tungsten (110) planes. This again confirms high quality GaN crystal grown on tungsten substrate.

It is understood that although all the presented drawings are related to tungsten substrate, it is only exemplary to the presented invention which, in other aspects, uses different single crystal or polycrystalline metallic substrates for GaN and related alloys' epitaxial growth using VPE technique.

What is claimed is:

1. A method of epitaxial growth of Aluminum-Gallium-Indium-Nitride over metallic substrate using Vapor Phase Epitaxy technique with controlled time moments and durations for activation of the sources of chemical components of the deposition reaction.

2. A method of epitaxial growth of Aluminum-Gallium-Indium-Nitride of claim 1, where the said metallic substrate is a single crystal substrate lattice matched to the Aluminum-Gallium-Indium-Nitride material grown.

3. A method of epitaxial growth of Aluminum-Gallium-Indium-Nitride of claim 1, where the said metallic substrate is a single crystal substrate partially lattice matched to the Aluminum-Gallium-Indium-Nitride material grown.

4. A method of epitaxial growth of Aluminum-Gallium-Indium-Nitride of claim 1, where the said metallic substrate is a single crystal substrate of arbitrary shape not lattice matched to the Aluminum-Gallium-Indium-Nitride material grown.

5. A method of epitaxial growth of Aluminum-Gallium-Indium-Nitride of claim 1, where the said metallic substrate is a polycrystalline substrate of arbitrary shape.

6. A method of epitaxial growth of Aluminum-Gallium-Indium-Nitride over metallic substrate using Vapor Phase Epitaxy technique with simultaneous activation of the sources of chemical components of the deposition reaction.

7. A method of epitaxial growth of Aluminum-Gallium-Indium-Nitride of claim 6, where the said metallic substrate is a single crystal substrate lattice matched to the Aluminum-Gallium-Indium-Nitride material grown.

8. A method of epitaxial growth of Aluminum-Gallium-Indium-Nitride of claim 6, where the said metallic substrate is a single crystal substrate partially lattice matched to the Aluminum-Gallium-Indium-Nitride material grown.

9. A method of epitaxial growth of Aluminum-Gallium-Indium-Nitride of claim 6, where the said metallic substrate is a single crystal substrate of arbitrary shape not lattice matched to the Aluminum-Gallium-Indium-Nitride material grown.

10. A method of epitaxial growth of Aluminum-Gallium-Indium-Nitride of claim 6, where the said metallic substrate is a polycrystalline substrate of arbitrary shape.

11. An epitaxial film of Aluminum-Gallium-Indium-Nitride grown using the method of one of the claims 1-10.
